(19) United States
(12) Patent Application Publication
(10) Pub. No.: US 2013/0202898 A1
(43) Pub. Date: Aug. 8, 2013

(54) METHOD FOR FABRICATING SEMICONDUCTOR NANOWIRE AND SEMICONDUCTOR NANOSTRUCTURE

(71) Applicants: Hsing-Yu Tuan, Hsinchu (US); Fang-Wei Yuan, Hsinchu (TW)

(72) Inventors: Hsing-Yu Tuan, Hsinchu (US); Fang-Wei Yuan, Hsinchu (TW)

(73) Assignee: NATIONAL TSING HUA UNIVERSITY, Hsinchu (TW)

(21) Appl. No.: 13/476,122

(22) Filed: May 21, 2012

(30) Foreign Application Priority Data
Feb. 3, 2012 (TW) 101103447

(51) Int. Cl. B32B 15/04; B32B 15/14; H01L 21/20; B32B 19/04; B82Y 30/00; B82Y 99/00; B82Y 40/00

(52) U.S. Cl. 428/450; 438/478; 428/457; 257/E21.09; 977/762; 977/890

(57) ABSTRACT

A method for fabricating semiconductor nanowire includes the following steps: providing a metal substrate in a reactor; filling the reactor with an inert gas; heating and maintaining the reactor in a reaction temperature, raising the pressure in the reactor to a first predetermined pressure, and then passing a reacting precursor into the reactor; keeping passing the reacting precursor to raising the pressure of the reactor to a second predetermined pressure; and, maintaining the second predetermined pressure for a predetermined duration, so as to form semiconductor nanowires on the metal bulk. Accordingly, the method of the invention is capable of forming semiconductor nanowires on metal substrate, so that the processes for fabricating semiconductor nanowires can be simplified.

### BACKGROUND OF THE INVENTION

1. Field of the Invention

The present invention relates to a method for fabricating semiconductor nanowire, and more particularly to a fabricating method capable of forming semiconductor nanowires on metal substrate.

2. Description of the Prior Art

Semiconductor nanowires exhibit a number of unique features of optical, electrical, and mechanical properties, owing to their relatively high surface to volume ratio. All these features make semiconductor nanowires especially attractive for future electronic and photonic nano-devices, such as field effect transistor, photovoltaic cell, biosensor, or chemosensors.

In recent years, the fabrication methods of semiconductor nanowires have been proposed and developed, wherein the most common and efficient method is using the metallic nanoparticles as catalyst, and passing a reacting precursor into the reactor under a certain temperature and pressure, leading to the formation of semiconductor nanowires on the silicon substrate of reactor. In general, the conventional methods for fabricating semiconductor nanowires are performed in 1,000 degree C. or more. Take the silicon nanowires as an example, when the fabricating process is performed under the temperature mentioned above, Si atoms of the reacting precursor would diffuse into the metallic nanoparticles, and formed the liquid alloy; and if the Si atoms continue to diffuse, the liquid alloy would become supersaturation, developing a two-phase mixture. Due to precipitating the supersaturated Si atoms on the liquid-solid interface needs less energy than secondary crystallization, the Si atoms would be precipitated on the formed liquid-solid interface and grow silicon nanowires. However, the silicon nanowires fabricated by the conventional method may have remaining metallic nanoparticles at one end or on outer sides, wherein theses remaining metallic nanoparticles may affect the quality of semiconductor nanowires.

According to the growth mechanism described above, the growth of semiconductor nanowires uses metallic nanoparticles to catalyze their growth, and therefore the metallic nanoparticles should be synthetized before growing semiconductor nanowires. However, the synthesis of metallic nanoparticles is quite onerous, this causes the fabrication process of semiconductor nanowires to be complex and affects the costs.

Take a common method for fabricating metallic nanoparticles as an example, metal film is deposited on a substrate first, and then metallic nanoparticles are formed on the substrate by high temperature sintering, afterward semiconductor nanowires manufacturing process can be performed on the substrate directly. The method for fabricating metallic nanoparticles described above utilizes expensive equipment, and leading to higher costs. In general, a silicon dioxide or silicon wafer is adopted as the substrate so as to prevent the metal film reacting with the substrate during the sintering process.

Besides, another method for fabricating metallic nanoparticles is to synthesize the metallic nanoparticles directly by the chemical synthesis, and then configuring the metallic nanoparticles on the surface of substrate with active agent. However, this method still involves complex chemical reaction and purification process, and the size of nanoparticles during synthesis is hard to control. Furthermore, the inflexibility and fragileness of the substrate cause inconvenience for further application of the semiconductor nanowires.

Accordingly, the conventional methods for fabricating metallic nanoparticles still have many problems need to be solved.

### SUMMARY OF THE INVENTION

Therefore, in order to improve the problem described previously, a scope of the present invention is to provide a method for fabricating semiconductor nanowire.

According to an embodiment, the method for fabricating semiconductor nanowire comprises following steps: providing a metal substrate in a reactor; filling the reactor with an inert gas; heating and maintaining the reactor in a reaction temperature, raising the pressure in the reactor to a first predetermined pressure, and then passing a reacting precursor into the reactor; keeping passing the reacting precursor to raising the pressure of the reactor to a second predetermined pressure larger than the first predetermined pressure; and maintaining the second predetermined pressure for a predetermined duration, so as to form at least one semiconductor nanowire on the metal substrate.

Another scope of the present invention is to provide a semiconductor nanostructure for improving the problem mentioned previously.

According to an embodiment, the semiconductor nanostructure comprises a semiconductor nanowire which is formed on a metal substrate directly. The method for fabricating the semiconductor nanowire of this embodiment comprises following steps: providing a metal substrate in a reactor; filling the reactor with an inert gas; heating and maintaining the reactor in a reaction temperature, raising the pressure in the reactor to a first predetermined pressure, and then passing a reacting precursor into the reactor; keeping passing the reacting precursor to raising the pressure of the reactor to a second predetermined pressure larger than the first predetermined pressure; and maintaining the second predetermined pressure for a predetermined duration, so as to form at least one semiconductor nanowire on the metal substrate.

Many other advantages and features of the present invention will be further understood by the detailed description and the accompanying sheet of drawings.

### BRIEF DESCRIPTION OF THE APPENDED DRAWINGS

FIG. 1 is a flowchart illustrating a method for fabricating semiconductor nanowires according to an embodiment of the invention.

FIG. 2 is a scanning electron micrograph (SEM) image demonstrating a semiconductor nanostructure according to another embodiment of the invention.

FIG. 3 is a scanning electron micrograph (SEM) image demonstrating a semiconductor nanostructure according to another embodiment of the invention.

FIG. 4 is a scanning electron micrograph (SEM) image demonstrating a semiconductor nanostructure according to another embodiment of the invention.

To facilitate understanding, identical reference numerals have been used, where possible to designate identical elements that are common to the figures.

### DETAILED DESCRIPTION OF THE INVENTION

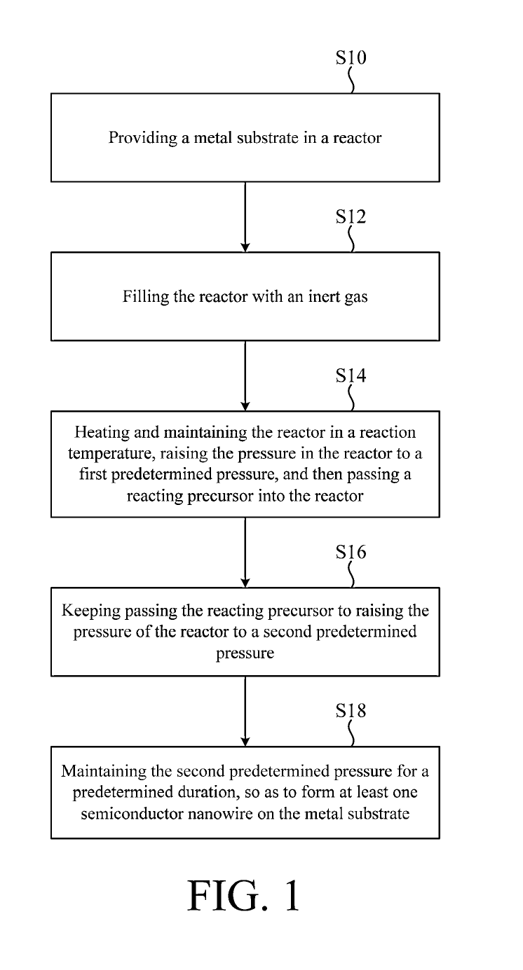

Please refer to FIG. 1. FIG. 1 is a flowchart illustrating a method for fabricating semiconductor nanowires according to an embodiment of the invention.

As shown in FIG. 1, the method for fabricating the semiconductor nanowires of this embodiment comprises following steps: step S10: providing a metal substrate in a reactor; step S12: filling the reactor with an inert gas; step S14: heating and maintaining the reactor in a reaction temperature, raising the pressure in the reactor to a first predetermined pressure, and then passing a reacting precursor into the reactor; step S16: keeping passing the reacting precursor to raising the pressure of the reactor to a second predetermined pressure larger than the first predetermined pressure; and step S18: maintaining the second predetermined pressure for a predetermined duration, so as to form at least one semiconductor nanowire on the metal substrate.

At steps S10 and S12 of the embodiment, metal substrate can be any form of bulk metal material, including but not limited to titanium reactor. In actual application, the reactor can be placed into a glove box first, and then filling the reactor with an inert gas. Therefore, the interior of the reactor became an anhydrous and anoxic environment so as to prevent the deterioration of the bulk metal material and the semiconductor nanowires during the process.

At step S14, the internal temperature of the reactor can be heated up to a reaction temperature of 400° C. by a heating unit, and the pressure in the reactor can be raised to a first predetermined pressure of 5.5 MPa by a pressure controller. To be noticed, the reaction temperature and the first predetermined pressure include, but not limited to the values mentioned above, they can be adjusted depending on the type or size of the bulk metal material, reactor, and the reacting precursor.

Under the reaction temperature and the first predetermined pressure mentioned above, a reacting precursor used for growing the semiconductor nanowires is passed into the reactor. Subsequently, keep passing the reacting precursor to raising the pressure of the reactor to a second predetermined pressure of 10.3 MPa. By the same token, the second predetermined pressure can be adjusted according to the factors mentioned above. In this embodiment, the reacting precursor is formed by adding monophenylsilane (MPS) to anhydrous benzene for dilution, and the concentration range of monophenylsilane can be between 0.5 M and 1.0 M and are not limited to the description above. MPS is a Si precursor which can be decomposed within a high temperature environment (over 400° C.) so as to provide Si atoms for growing semiconductor nanowires. Therefore, the semiconductor nanowires of the embodiment are Si nanowires. In actual application, the reacting precursor can be adopted according to the type of semiconductor nanowires expected to obtain. For example, when the semiconductor nanowires expected to obtain are Ge nanowires, a Ge precursor can be adopted to form the reacting precursor with proper parameters (reaction temperature, first predetermined pressure, the second predetermined pressure, and predetermined duration).

Once the second predetermined pressure is attained, stop passing the reacting precursor into the reactor so as to maintain and control the second predetermined pressure in the reactor. To be more precise, take a control method for as an example, the reactor can be connected to a high pressure stainless-steel tube, and the other end of the high pressure stainless-steel tube is connected with a six-way valve served as an injection ring of reacting precursor, and meanwhile, the six-way valve is connected to a high-pressure liquid chromatograph (HPLC). The reacting precursor prepared previously can be injected to the six-way valve, and the high-pressure liquid chromatograph may push the reacting precursor into the reactor. When the second predetermined pressure is attained in the reactor, switch off the high-pressure liquid chromatograph immediately, so that the second predetermined pressure can be maintained.

As step S18 illustrated, the second predetermined pressure is maintained for a predetermined duration, so as to form at least one semiconductor nanowire on the metal substrate. Wherein the predetermined duration can be 5 minutes, but the present invention is not limited to this, it can be adjusted depending on the demands of user. Under the reaction temperature and the second predetermined pressure mentioned above, the reacting precursor form a supercritical fluid, causing the bulk metal material to catalyze MPS to grow Si nanowire on the surface of the bulk metal material. After the predetermined duration, drop the reaction temperature of the reactor to ambient temperature first, and then the bulk metal material and the Si nanowires thereon can be taken out together.

With the method for fabricating the semiconductor nanowires of this embodiment, semiconductor nanowires can be grown on bulk metal material directly and not limited to be grown on Si substrate only. Moreover, this method need not fabricate metallic nanoparticles, so the costs and complexity of the fabrication process of semiconductor nanowires can be reduced greatly. In actual application, the bulk metal material can be Ag, Al, Cu, Fe, Ni, Ti, or Pb. Due to the bulk metal material can be purchased directly, there is a simple surface finishing need to be proceeded before providing the bulk metal material into the reactor, such as removing oxide layer from the surface of bulk metal material with abrasive paper or utilizing toluene and acetone for cleaning the bulk metal material. To be noticed, if the bulk metal material is Pb-based, the bulk metal material can be loaded on silicon wafer first, and then placed into the reactor together.

The phase diagram between Si and the bulk metal materials described above can be categorized into three categories, and the detailed descriptions are as follows.

Pb is the metal of the first category. Owing to the melting point of Pb is 327.5° C. lower 100° C. than the reaction temperature, Pb is mainly present in liquid phase and served as catalyst particle. During the process of synthesis, Pb may form a supersaturated liquid alloy with Si and further expedite the growth of Si nanowire. To be noticed, the method for fabricating semiconductor nanowires can be performed on the other metals which have similar phase diagram with Pb to grow Si nanowires directly, such as Zn, In, Sn, Ga, or Cd.

Ag and Al are the metal of the second category. The eutectic temperature of Ag/Si and Al/Si are 835° C. and 577° C. respectively which are larger than the reaction temperature, and therefore Ag and Al may form supersaturated alloy with Si at solid state and further expedite the growth of Si nanowire.

Fe, Ni, Ti, and Cu are categorized into the third category. The eutectic temperature of Fe/Si, Ni/Si, Ti/Si, and Cu/Si are over 800° C., so these metals expedite the growth of Si nanowire at solid state. However, these metals have higher solubility of metal and Si, this feature makes the metals be liable to form metal silicides even when the reaction temperature is lower (e.g., below 500° C.). Subsequently, the metal silicides become nanoscale under continuous atomic diffusion and further to grow Si nanowire.

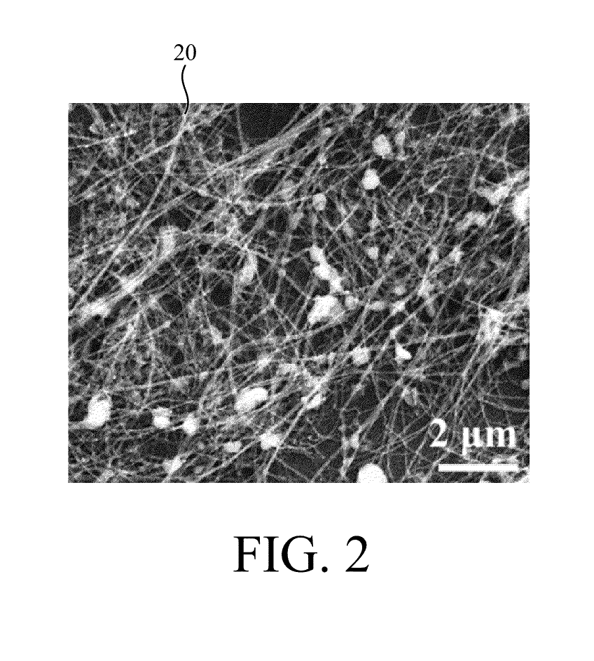

Please refer to FIG. 2. FIG. 2 is a scanning electron micrograph (SEM) image demonstrating a semiconductor nanostructure according to another embodiment of the invention. To be noticed, the bulk metal material in this embodiment is Pb, i.e., the metal of the first category described above. Moreover, the semiconductor nanostructure of FIG. 2 is fabricated according to the method of FIG. 1, and FIG. 2 is a SEM image of the surface of Pb bulk material. As shown in FIG. 2, the Si nanowires 20 with long length and high density are grown on the surface of Pb bulk material. In actual application, Pb nanoparticles can be observed at the ends of Si nanowires 20 through transmission electron microscope.

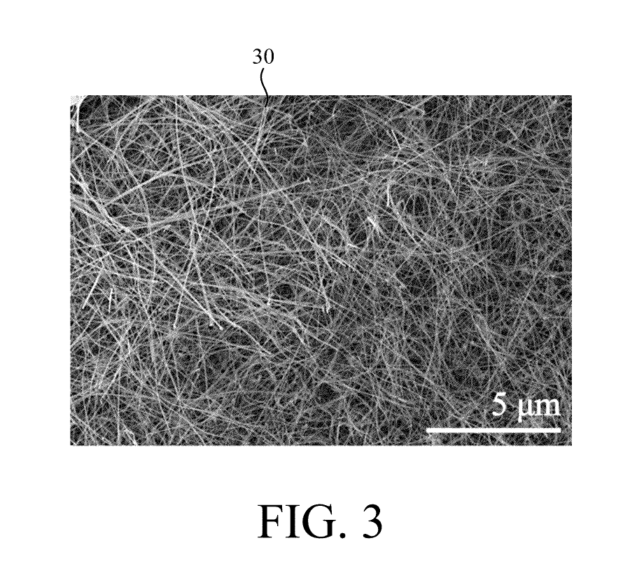

Please refer to FIG. 3. FIG. 3 is a scanning electron micrograph (SEM) image demonstrating a semiconductor nanostructure according to another embodiment of the invention. The bulk metal material in this embodiment is Al, i.e., the metal of the second category. Moreover, the semiconductor nanostructure of FIG. 3 is fabricated according to the method of FIG. 1, and FIG. 3 is a SEM image of the surface of Al bulk material. As shown in FIG. 3, the Si nanowires 30 with long length and high density are grown on the surface of Al bulk material.

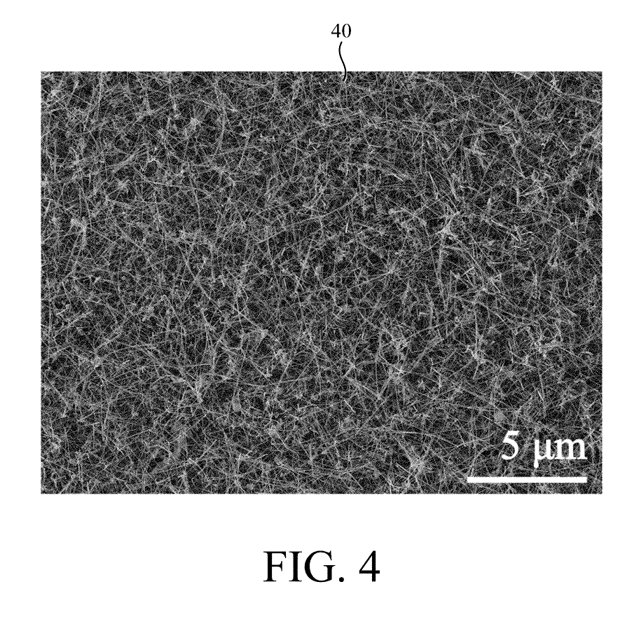

Please refer to FIG. 4. FIG. 4 is a scanning electron micrograph (SEM) image demonstrating a semiconductor nanostructure according to another embodiment of the invention. The bulk metal material in this embodiment is Cu, i.e., the metal of the third category. Moreover, the semiconductor nanostructure of FIG. 4 is fabricated according to the method of FIG. 1, and FIG. 4 is a SEM image of the surface of Cu bulk material. As shown in FIG. 4, the Si nanowires 40 with high density are grown on the surface of Cu bulk material.

According to the embodiments mentioned above, Si nanowires are grown on the bulk metal material directly, thus the adhesion force between Si nanowires and the bulk metal material is strong. Take the efficiency of field emission as an example, the structure can provide a well electron transfer environment and enhance the efficiency of field emission. By the same token, the Si nanowires grown on the bulk metal material can be applied to each field directly, such as biomedical field and/or photoelectric field, and served as electronic components. For example, Si nanowires can be grown on electroconductive substrate directly and served as cell electrode materials, field emission electrodes or optoelectric devices. On the other hand, in-situ method can be used for observing the reaction between the metal and Si nanowires.

The Si nanowires fabricated according to the embodiments described previously can be removed from the bulk metal material for further application. Meanwhile, the bulk metal material without Si nanowires can be reused to fabricate Si nanowires again. Furthermore, the bulk metal material includes but not limited to be a bulk, it can be other forms of metal, such as copper wire, silver wire, iron wire, aluminium foil, copper cylinder or copper mesh, and therefore the semiconductor nanowires can be further applied.

Accordingly, the method of the invention is capable of forming semiconductor nanowires on metal substrate, so that the processes for fabricating semiconductor nanowires can be simplified, and meanwhile, the costs and complexity of the fabrication process of semiconductor nanowires can be reduced greatly.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method for fabricating semiconductor nanowire, comprising the following steps of:
providing a metal substrate in a reactor;
filling the reactor with an inert gas;
heating and maintaining the reactor in a reaction temperature, raising the pressure in the reactor to a first predetermined pressure, and then passing a reacting precursor into the reactor;
keeping passing the reacting precursor to raising the pressure of the reactor to a second predetermined pressure larger than the first predetermined pressure; and
maintaining the second predetermined pressure for a predetermined duration, so as to form at least one semiconductor nanowire on the metal substrate.

2. The method for fabricating semiconductor nanowire of claim 1, wherein the reactor is a titanium reactor.

3. The method for fabricating semiconductor nanowire of claim 1, wherein the reaction temperature is larger than 400 degree C.

4. The method for fabricating semiconductor nanowire of claim 1, wherein the first predetermined pressure is 5.5 MPa, and the second predetermined pressure is 10.3 MPa.

5. The method for fabricating semiconductor nanowire of claim 1, wherein the metal substrate comprises at least one of the group of argentum (Ag), aluminium (Al), copper (Cu), ferrum (Fe), nickel (Ni), titanium (Ti), and/or plumbum (Pd).

6. The method for fabricating semiconductor nanowire of claim 5, wherein the metal substrate is a Pd substrate, and the method further comprises the following step:
placing the Pd substrate on a silicon wafer, and putting the Pd substrate and the silicon wafer into the reactor.

7. The method for fabricating semiconductor nanowire of claim 1, wherein the reacting precursor is formed by adding monophenylsilane to anhydrous benzene, and the concentration range of monophenylsilane is between 0.5 M and 1.0 M.

8. A semiconductor nanostructure, comprising:
a semiconductor nanowire, formed on a metal substrate directly.

9. The semiconductor nanostructure of claim 8, wherein the metal substrate comprises at least one of the group of argentum (Ag), aluminium (Al), copper (Cu), ferrum (Fe), nickel (Ni), titanium (Ti), and/or plumbum (Pd).

10. The semiconductor nanostructure of claim 8, wherein the semiconductor nanostructure comprises at least one of silicon nanowire and/or germanium nanowire.
